(19) United States
(12) Patent Application Publication
(10) Pub. No.: US 2008/0023320 A1
(43) Pub. Date: Jan. 31, 2008

(54) Method for Manufacturing Separator for Fuel Cell

(75) Inventors: Koji Kobayashi, Sayama-shi (JP); Yutaka Takeuchi, Sayama-shi (JP); Masashi Takagaki, Sayama-shi (JP); Toshiki Kawamura, Wako-shi (JP)

Correspondence Address: RANKIN, HILL, PORTER & CLARK LLP, 38210 Glenn Avenue, WILLOUGHBY, OH, 44094-7808, US

(73) Assignee: HONDA MOTOR CO., LTD., Tokyo (JP)

(21) Appl. No.: 11/570,834

(22) PCT Filed: May 10, 2005
(86) PCT No.: PCT/JP05/08841

§ 371 Date: Dec. 18, 2006

(30) Foreign Application Priority Data
Jun. 22, 2004 (JP) 2004-183817

(51) Int. Cl. C23C 14/00

(52) U.S. Cl. 204/192.32

(57) ABSTRACT

A method for manufacturing a titanium separator to be used in a fuel cell. In this method, an oxide film (66) is removed from a surface (21) of a separator material (51) by sputtering. Then, separator material is heated within a range of 350°C.-500°C. in a nitriding atmosphere which includes a nitriding gas (55), and a plasma nitriding process is performed to form a titanium film (71) on the surface of the separator material.

### TECHNICAL FIELD

The present invention relates to a method for manufacturing a fuel cell separator, and particularly relates to a method for manufacturing a fuel cell separator for producing a separator from a titanium sheet material.

### BACKGROUND ART

A solid-state polyelectrolyte fuel cell is a cell having a structure in which fuel cell elements are stacked in numerous layers, and from which the desired output is obtained. A fuel cell comprises a membrane electrode assembly (hereinafter abbreviated as “MEA”), and separators provided on both sides thereof.

The separators must have sufficient strength because pressure is applied to the separators when fuel cell elements are stacked together, but the separators must also be thin in order to keep the fuel cell compact.

Thus, metal separators are preferably used in order to ensure strength against the pressure applied during stacking and to reduce the size of the element stack.

There are metal separators in which titanium is used as a metal material, as disclosed in JP-A-2000-353531.

JP-A-2000-353531 discloses a separator wherein a titanium (Ti) film is formed by spraying on a stainless steel member, the stainless steel member is press-worked to form a separator, the stainless steel member is subsequently heated to a temperature of 973 K (about 700° C.) for five hours to perform nitriding, and a nitride film is formed on a surface of the titanium film.

The separator surface is less likely to oxidize and formation of an oxide film is inhibited by forming the nitride film on the titanium film.

Inhibiting the formation of an oxide film on the surfaces of separators allows the contact resistance (i.e., electrical resistance) of the separators to be minimized when the separators are brought into contact with an MEA on both sides.

With separators thus configured, however, the metal material must be heated to a high temperature (about 700° C.) and the nitriding treatment must be performed in this state when a nitride film is formed on the titanium film surface. There is thus a risk that the metal material will be strained when the metal material is heated to the high temperature (about 700° C.). Therefore, there is a risk that the separators will not be able to form uniform contact with the MEA when incorporated into a fuel cell.

In view of this, a technique is needed for minimizing the contact resistance and to prevent separator strain.

### DISCLOSURE OF THE INVENTION

According to the present invention, there is provided a method for manufacturing a titanium separator for use in a fuel cell, said method comprising the steps of: press-forming a titanium sheet into a separator blank with grooves formed for conducting gas or water; sputtering, after the separator blank is placed in a reducing atmosphere containing a reducing gas, ions produced by ionizing the reducing gas onto a surface of the separator blank to thereby remove an oxide film generated on the separator blank surface; and plasma-nitriding the separator blank surface by, after the oxide-film-removed separator blank is placed in a nitriding atmosphere containing a nitriding gas, heating the separator blank to a temperature of 350 to 500° C. and then causing ions produced by plasma-nitriding the nitriding gas to collide with the separator blank surface to thereby form a nitrogen diffused layer on the surface.

The oxide film (i.e., natural oxide film) is removed from the surface of the separator blank by sputtering whereby the nitrogen is diffused more readily on the surface of the separator blank during plasma nitriding. The separator on whose surface the nitrogen is adequately diffused can thereby be obtained merely by heating the separator blank to a temperature of 350 to 500° C.

The adequate diffusing of the nitrogen on the separator surface makes the separator surface less likely to oxidize, and inhibits the formation of an oxide film (natural oxide film). The contact resistance (i.e., electrical resistance) of the separator can be thereby reduced when the separator is brought into contact with either side of the MEA.

Furthermore, the heating temperature of the separator blank can be reduced to a range of 350 to 500° C. during plasma nitriding, which will make it possible to prevent strain from occurring in the separator that has been subjected to plasma nitriding. The separator can thereby make uniform contact with the MEA when the separator is incorporated into a fuel cell.

The reason the heating temperature is reduced to a range of 350 to 500° C. during plasma nitriding shall be described hereunder.

If the heating temperature is less than 350° C., the heating temperature will be too low to adequately diffuse the nitrogen on the separator surface. The heating temperature is therefore set to 350° C. or higher so that the nitrogen will be adequately diffused on the separator surface.

If the heating temperature exceeds 500° C., the heating temperature will be too high and the separator may be subjected to strain. The heating temperature is therefore set to 500° C. or less so that the separator will not be subjected to strain.

Plasma nitriding is also referred to as ion nitriding.

An advantage of the present invention is that the heating temperature is accordingly reduced to a range of 350 to 500° C. during plasma nitriding, thereby preventing the separator from being subjected to strain and allowing the separator to contact the MEA in a uniform manner.

Preferably, the reducing gas contains at least one gas selected from the group containing hydrogen gas, halide gas, and ammonia gas, and accordingly can be selected from a variety of gases, making it readily procurable.

In a preferred form, the nitriding gas contains at least one gas selected from the group containing hydrogen gas and ammonia gas, and accordingly can be selected from a variety of gases, making it readily procurable. Additionally, ammonia gas can be also used as a reducing gas when the ammonia gas is used as a nitriding gas, so that the equipment can be simplified.

Desirably, the sputtering and plasma-nitriding steps are performed simultaneously. This simplifies the method of manufacture of the separator. The time required to manufacture a separator can accordingly be reduced and productivity can be increased.

### BRIEF DESCRIPTION OF THE DRAWINGS

FIG. 1 is a sectional view showing a separator manufactured by a method for manufacturing a fuel cell separator according to a first embodiment of the present invention;

FIG. 2 is a sectional view showing an apparatus for manufacturing the fuel cell separator according to the present invention;

FIGS. 3A and 3B are views showing the steps for press-forming the separator in the manufacturing method according to the first embodiment of the present invention;

FIGS. 4A and 4B are views showing a state in which an oxide film is formed on a surface of the separator in the manufacturing method according to the first embodiment of the invention, while FIG. 4B is an enlarged view of 4B in FIG. 3B;

FIGS. 5A and 5B are views showing an example in which hydrogen gas and nitrogen gas are ionized in the manufacturing method according to the first embodiment of the present invention;

FIGS. 6A through 6C are views showing an example of diffusing nitrogen in the surface of the separator in the manufacturing method according to the first embodiment of the present invention;

FIG. 7A is a view showing an example in which a separator produced by the manufacturing method according to the first embodiment of the present invention is used in a fuel cell, while FIG. 7B is an enlarged view of portion 7B in FIG. 7A;

FIG. 8 is a graph showing a contact resistance of the separator produced by the manufacturing method according to the first embodiment of the present invention;

FIGS. 9A and 9B are views showing an example in which hydrogen gas is ionized in a method for manufacturing a fuel cell separator, according to a second embodiment of the present invention;

FIGS. 10A and 10B are views showing an example in which nitrogen gas is ionized in the manufacturing method according to the second embodiment of the present invention; and

FIGS. 11A through 11C are views showing an example of diffusing nitrogen in the surface of the separator in the manufacturing method according to the second embodiment of the present invention.

### BEST MODE FOR CARRYING OUT THE INVENTION

A method for manufacturing a separator according to the present invention will be described in detail below with reference to the accompanying drawings.

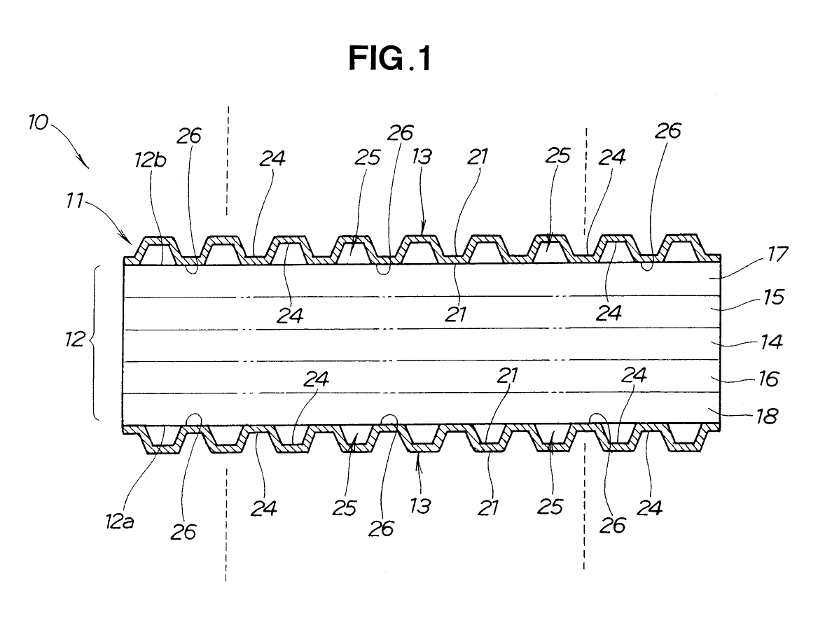

A separator produced by a manufacturing method according to a first embodiment will first be described based on FIG. 1.

The fuel cell 10 shown in FIG. 1 is obtained by stacking and unitizing numerous layers of fuel cell elements (i.e., unit fuel cells) 11. The fuel cell elements 11 have a configuration in which titanium separators 13, 13 are disposed on two sides 12a, 12b of a membrane electrode assembly (MEA) 12.

The MEA 12 comprises positive and negative electrode layers 15 and 16 disposed on both sides of an electrolyte membrane 14, a positive-side diffusion layer 17 disposed outside of the positive-electrode layer 15, and a negative-side diffusion layer 18 disposed outside of the negative-electrode layer 16.

The positive-electrode layer 15 and the positive-side diffusion layer 17 are sometimes collectively referred to as “a positive-electrode layer,” and the negative-electrode layer 16 and the negative-side diffusion layer 18 are sometimes collectively referred to as “a positive-electrode layer”.

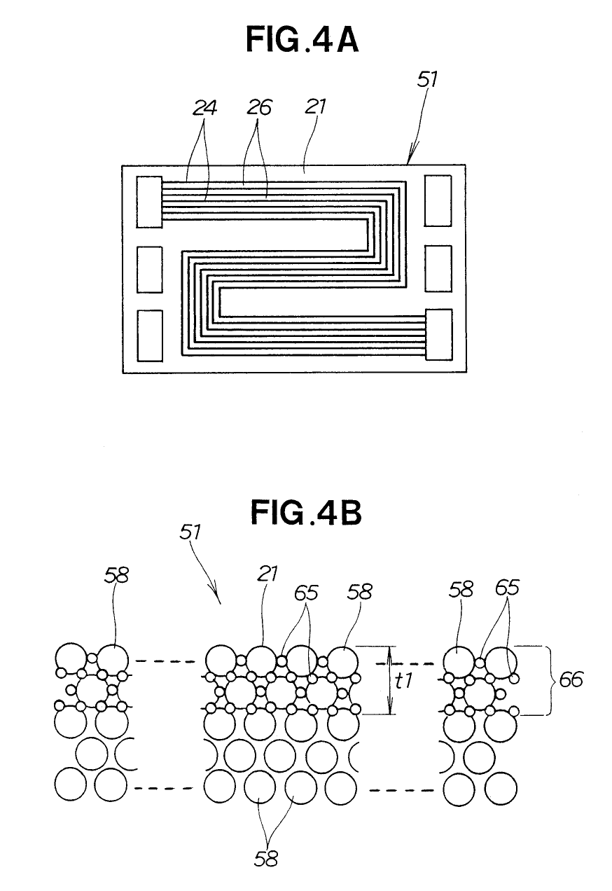

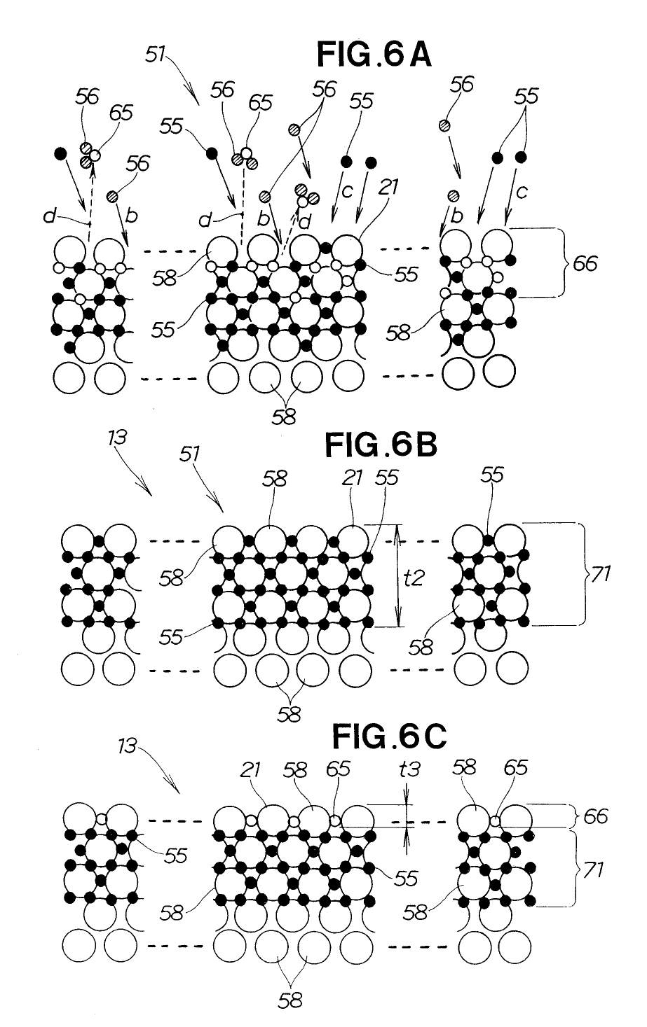

In the titanium separators 13, oxide films 66 (see FIG. 4B) are removed from both surfaces 21, 21 by sputtering, and nitrogen is diffused in the surfaces 21, 21 by plasma nitriding to form a titanium nitride film (diffusion layer) 71 (see FIG. 6B).

Each of the separators 13 is provided with a plurality of grooves 24 on the surfaces 21, 21 by forming the surfaces 21, 21 into a concavoconvex shape.

The separators 13 are brought into contact with the two surfaces 12a, 12b of the MEA 12, whereby the grooves 24 are blocked off at the two surfaces 12a, 12b of the MEA 12 to form a plurality of gas-conducting channels 25 or a plurality of water-conducting channels 25.

A plurality of convexities 26 on the surfaces 21, 21 of the separators 13 is in contact with the two surfaces 12a, 12b of the MEA 12. It is preferable to thereby minimize the contact resistance (i.e., the electrical resistance) of the convexities 26 (i.e., the surface 21) of the separators 12.

It is also preferable to minimize strain in the separators 12 in order to make the convexities 26 (i.e., the surface 21) on the separators 12 to properly contact the two surfaces 12a, 12b of the MEA 12.

Following is a description of a manufacturing method designed to minimize the contact resistance on the surface 21 of the separators 13 and the strain in the separators 12.

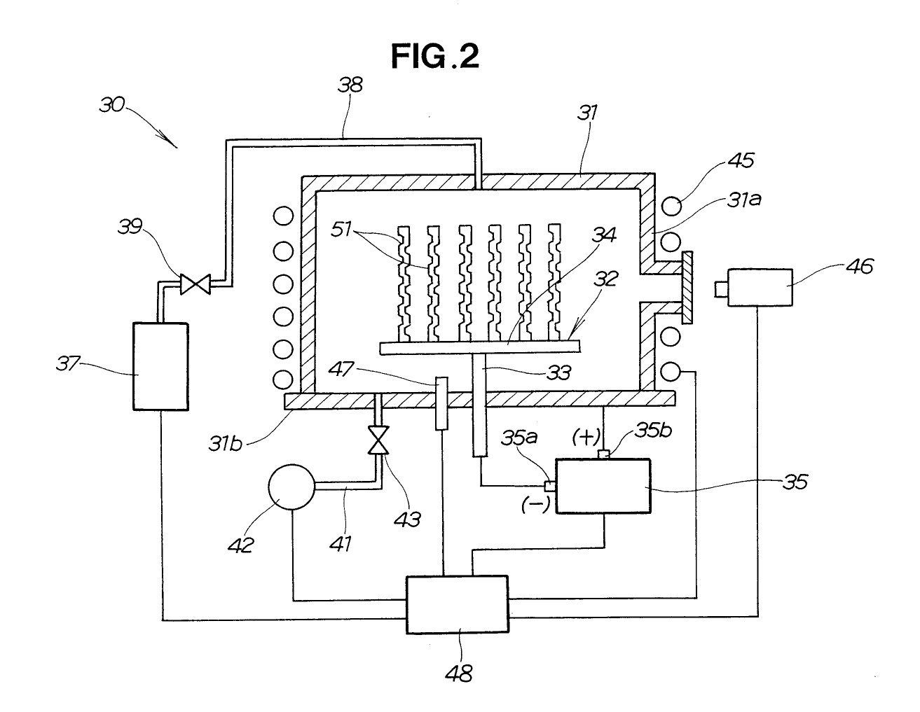

An apparatus for manufacturing a separator according to the invention is first described based on FIG. 2.

The apparatus 30 for manufacturing a fuel cell separator shown in FIG. 2 is provided with a mounting base 32 for mounting a plurality of separator blanks 51 disposed in a container 31.

A negative pole 35a of a DC power supply 35 is connected to a support part 33 of the mounting base 32. A positive pole 35b of the DC power supply 35 is connected to the container 31.

A gas source 37 is connected to the interior of the container 31 via a supply channel 38. A first on/off valve 39 is provided midway in the supply channel 38.

A vacuum pump 42 is connected to the interior of the container 31 via a discharge channel 41. A second on/off valve 43 is provided midway in the discharge channel 41.

A heater 45 is disposed on the outside of a wall part 31a of the container 31. A non-contact temperature sensor 46 is disposed so as to face the wall part 31a of the container 31. A gas pressure sensor 47 is disposed in the base 31b of the container 31.

A control unit 48 controls the DC power supply 35, the gas source 37, the vacuum pump 42, and the heater 45 on the basis of detection signals from the temperature sensor 46 and the gas pressure sensor 47.

The mounting base 32 comprises the support part 33 and a mounting plate 34 installed on top of the support part 33. The separator blanks 51 are placed vertically on the mounting plate 34 at prescribed intervals.

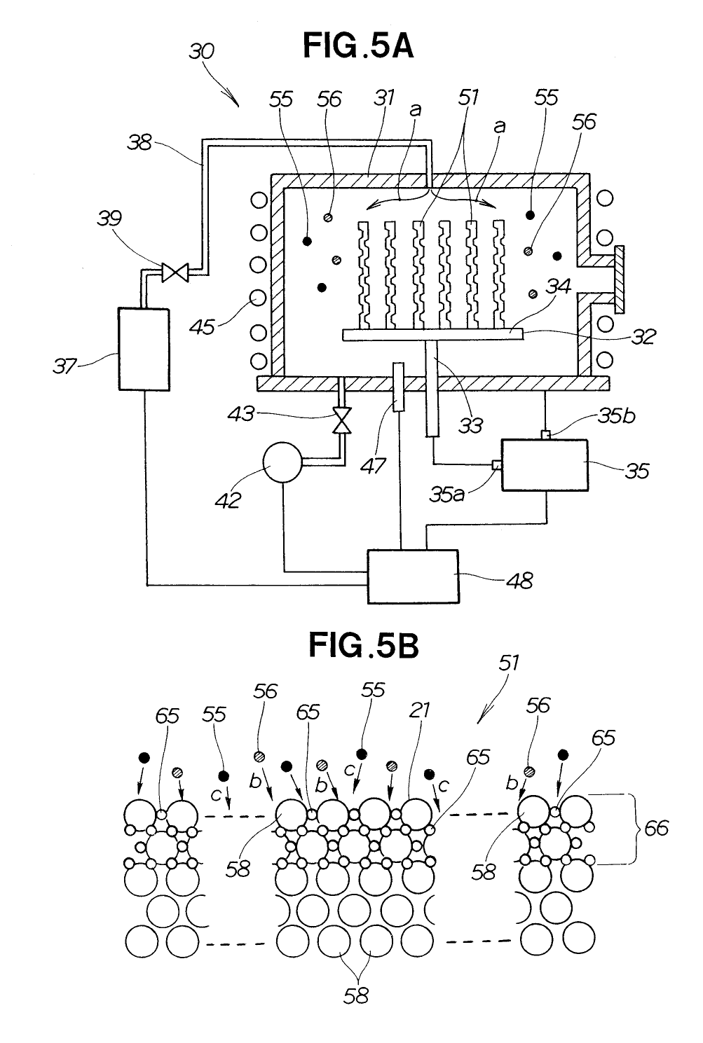

The gas source 37 supplies nitrogen (N₂) gas (nitriding gas) 55 (see FIG. 5A), and hydrogen (H₂) gas (reducing gas) 56 (see FIG. 5A) into the container 31.

The nitrogen gas 55 and hydrogen gas 56 may, for example, be in a proportion at which the nitrogen gas/hydrogen gas ratio is 7:3.

The separator manufacturing apparatus 30 is configured so as to generate a glow discharge between the container 31 and the mounting base 32 by placing the separator blanks 51 vertically on the mounting plate 34 at prescribed intervals, supplying the nitrogen gas 55 and hydrogen gas 56 from the gas source 37 into the container 31, and applying a prescribed voltage between the container 31 and the mounting base 32 from the DC power supply 35.

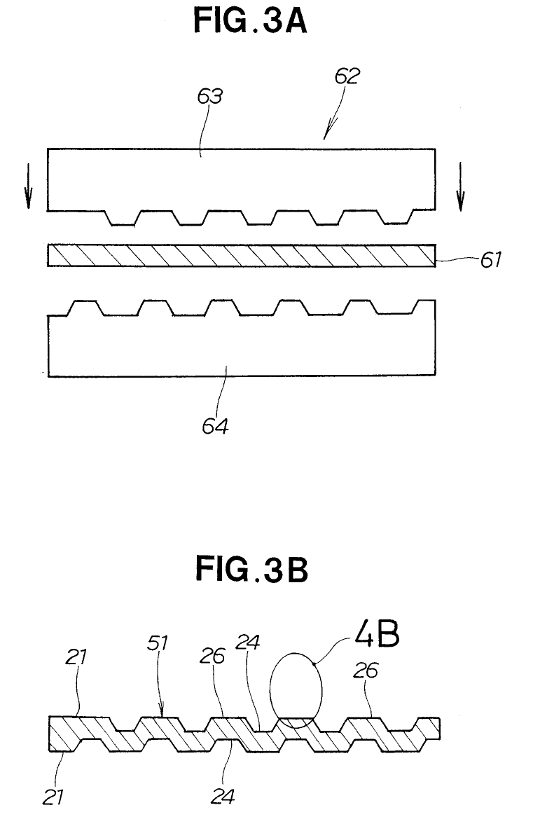

A method for manufacturing a fuel cell separator according to the invention is next described based on FIGS. 3A through 6C.

FIGS. 3A and 3B show the steps for press-forming a separator in the method for manufacturing a separator according to the first embodiment.

In FIG. 3A, a titanium sheet 61 is positioned in a pressing machine 62, and a movable die 63 of the pressing machine 62 is moved toward and clamped against a fixed die 64. The movable die 63 and the fixed die 64 are clamped together to press-form the titanium sheet 61.

In FIG. 3B, a titanium separator blank 51 is obtained by press-forming the titanium sheet 61 shown in FIG. 3A. The separator blank 51 has the grooves 24 for conducting gas or water. Convex parts of the separator blank 51 are convexities (contact parts) 26 in contact with the two sides 12a, 12b of the MEA 12 (see FIG. 1).

FIGS. 4A and 4B show a state in which an oxide film is formed on a separator surface.

FIG. 4A shows the separator blank 51 as viewed from the top. The grooves 24 for conducting gas or water are formed in one of the surfaces 21 of the separator blank 51, as are the convexities 26 in contact with the two sides 12a, 12b of the MEA 12 (see FIG. 1).

FIG. 4B shows portion 4B in FIG. 3B in magnified form. The surface 21 of the separator blank 51 is oxidized and the oxide film (natural oxide film) 66 is formed on the surface 21 during transportation of the separator blank 51 or by allowing the separator blank 51 to stand in the air. The oxide film 66 stabilizes when formed to a thickness t1 of 1 to 10 nm.

FIGS. 5A and 5B show an example in which hydrogen gas and nitrogen gas are ionized.

As shown in FIG. 5A, a plurality of separator blanks 51 is placed vertically on the mounting plate 34 at prescribed intervals.

The second on/off valve 43 is subsequently opened and the vacuum pump 42 is driven. The second on/off valve 43 is closed and the vacuum pump 42 is stopped, after which the second on/off valve 43 is opened and the nitrogen gas 55 and hydrogen gas 56 are supplied from the gas source 37 into the container 31 as indicated by arrows a.

The nitrogen gas 55 and hydrogen gas 56 are supplied so that the nitrogen gas 55 and hydrogen gas 56 in the container 31 are in a proportion at which the nitrogen gas/hydrogen gas ratio is, for example, 7:3.

Both a reducing atmosphere and a nitriding atmosphere are thereby created inside the container 31.

The pressure inside the container 31 is detected by the gas pressure sensor 47 and confirmed to be, for example, 67 to 1,333 Pa (0.5 to 10 Torr). The second on/off valve 43 is closed.

The container is heated by the heater 45 so that the treatment temperature reaches 350 to 500° C. The separator blanks 51 are heated to a range of 350 and 500° C.

In this state, a prescribed voltage is applied between the container 31 and the mounting base 32 from the DC power supply 35, whereby a glow discharge is generated between the container 31 and the mounting base 32.

In FIG. 5B, a glow discharge is generated and the nitrogen gas 55 and hydrogen gas 56 are each ionized.

The ionized hydrogen ions 56 are moved toward the surface 21 of each of the separator blanks 51 as indicated by arrows b.

The ionized nitrogen ions 55 are moved toward the surface 21 of each of the separator blanks 51 as indicated by arrows c.

FIGS. 6A through 6C show an example in which nitrogen is diffused in a separator surface.

In FIG. 6A, hydrogen ions 56 are moved toward the surface 21 of the separator blank 51 as indicated by arrows b, whereby the hydrogen ions 56 are caused to collide with the surface 21 of the separator blank 51, and sputtering is performed.

Sputtering causes the hydrogen ions 56 to react with oxygen 65 in the surface 21 of the separator blank 51 to create water vapor.

The oxide film 66 is removed from the surface 21 of the separator blank 51 by removing the oxygen 65 from the surface 21 as indicated by arrows d.

The nitrogen ions 55 are moved toward the surface 21 of the separator blank 51 as indicated by arrows c, whereby the nitrogen ions 55 are caused to collide with the surface 21 of the separator blank 51, and plasma nitriding is performed.

At this point, the oxide film 66 is removed from the surface 21 of the separator blank 51 by sputtering. The nitrogen 55 is thereby diffused more readily in the surface 21 of the separator blank 51 when the nitrogen ions 55 are caused to collide with the surface 21 of the separator blank 51 by plasma nitriding.

In FIG. 6B, the nitrogen 55 is diffused more readily in the surface 21 of the separator blank 51, making it possible to reduce the temperature of the plasma nitriding treatment to a range of 350 to 500° C. In other words, the nitrogen 55 can be adequately diffused in the surface 21 of the separator blank 51 merely by heating the separator blank 51 to a temperature of 350 to 500° C.

The separator 13 is obtained by completing plasma nitriding. The separator 13 is provided with a titanium nitride film 71 obtained by adequately diffusing the nitrogen 55 in the surface 21. The surface 21 of the separator 13 is thereby made less likely to oxidize.

The titanium nitride film 71 preferably has a thickness t2 of 0.1 to 3.0 μm. The titanium nitride film 71 is too thin to minimize the oxide film (natural oxide film) 66 when the film thickness t2 is less than 0.1 μm. The film thickness t2 is set to 0.1 μm or greater to minimize the oxide film (natural oxide film) 66.

On the other hand, when the film thickness t2 exceeds 3.0 μm, the titanium nitride film 71 is too thick to secure the toughness that is necessary for the separator. In addition, too much time is required to perform plasma nitriding, and it is more difficult to achieve increased productivity. The film thickness t2 is therefore set to 3.0 μm or less to provide the separator with the desired brittleness and to ensure the desired productivity.

In FIG. 6C, the surface 21 and the titanium nitride film 71 of the separator 13 are oxidized and the oxide film (natural oxide film) 66 is formed on the surface 21 during transportation of the separator 13 or by allowing the separator 13 to stand in the air.

The surface 21 of the separator 13 is less likely to oxidize, and formation of the oxide film (natural oxide film) 66 can be inhibited because the titanium nitride film 71 is formed on the surface 21 of the separator 13. The oxide film 66 is thereby kept extremely thin and stable at a thickness t3 of 0 to 1 nm.

The treatment temperature, i.e., the heating temperature of the separator blank 51 (see FIG. 6B), can be also reduced to a range of 350 to 500° C. during plasma nitriding. Strain can thereby be prevented in the separator 13 that is subjected to the plasma nitriding treatment.

The reason that the heating temperature (treatment temperature) was reduced to a range of 350 to 500° C. during the plasma nitriding treatment will be described herein.

The heating temperature is too low and the nitrogen 55 cannot be adequately diffused in the surface 21 of the separator 13 when the heating temperature is less than 350° C. The heating temperature was therefore set at 350° C. or greater to allow the nitrogen 55 to be adequately diffused in the surface 21 of the separator 13.

The heating temperature is too high and strain may develop in the separator 13 when the heating temperature exceeds 500° C. The heating temperature was therefore set at 500° C. or less to prevent strain from developing in the separator 13.

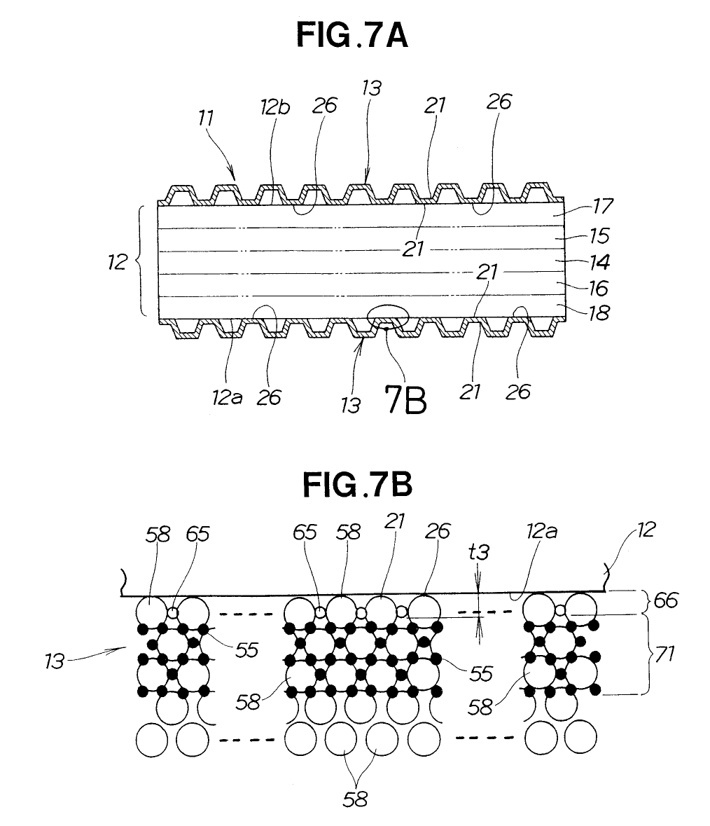

An example in which a separator produced by the method for manufacturing a fuel cell separator is used in a fuel cell will be next described based on FIGS. 7A and 7B.

In FIG. 7A, separators 13, 13 are disposed on two sides 12a, 12b of the MEA 12.

A surface 21 (specifically convexities 26) of one of the separators 13 is brought into contact with the side 12a of the MEA 12, and a surface 21 (specifically convexities 26) of the other separator 13 is brought into contact with the other side 12b of the MEA 12.

The heating temperature of a separator blank 51 (see FIG. 6B) is reduced to a range of 350 to 500° C. during the plasma nitriding treatment whereby strain is prevented from developing in the separators 13.

The surfaces 21, 21 (convexities 26) of the separators 13 can thereby form uniform contact with the two sides 12a, 12b of the MEA.

In FIG. 7B, keeping the thickness t3 of the oxide film 66 on the surface 21 in an extremely low and stable state makes it possible to minimize the contact resistance (i.e., electrical resistance) of the separators 13 when the surfaces 21 (convexities 26) of the separators 13 are brought into contact with the two sides 12a, 12b (side 12b is shown in FIG. 7A) of the MEA 12.

### EXAMPLES

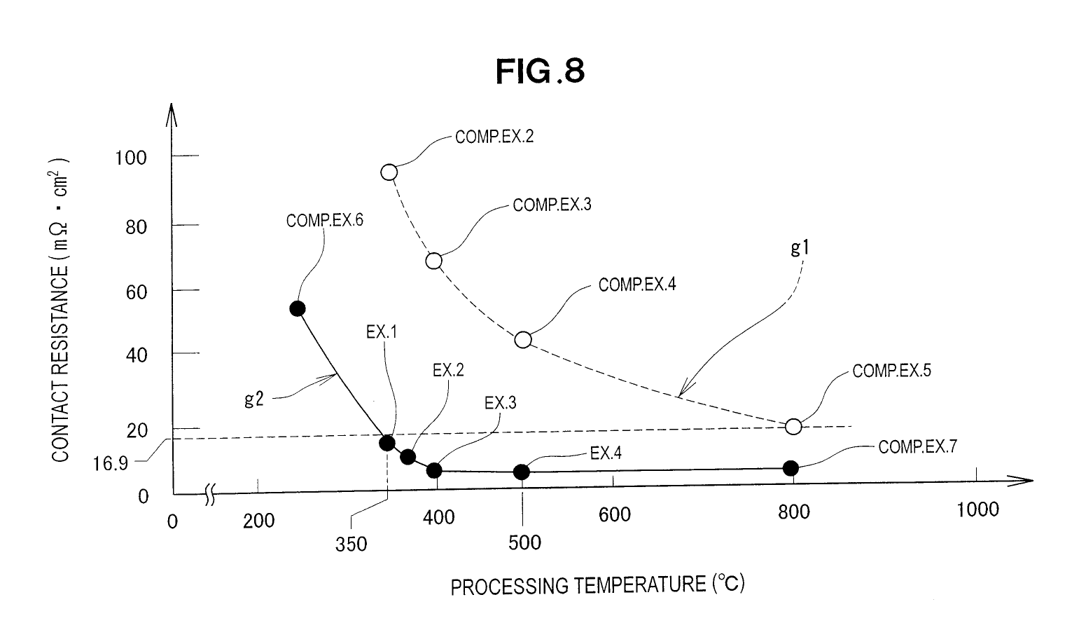

The reasons for setting the treatment temperature of plasma nitriding to a range of 350 to 500° C. will be described based on Table 1, comparative examples 1 through 7 shown as a graph in FIG. 8, and examples 1 through 4.

The treatment temperature has minimal effect on the sputtering treatment, and the treatment temperature needs to be considered only for the plasma nitriding treatment.

The titanium separators of comparative examples 1 through 7 and examples 1 through 4 are as described below:

TABLE 1

| | Treatment | | | | |
|---|---|---|---|---|---|
| | Conditions | | Results | | |
| | | Treatment | | Contact | |
| | N₂:H₂ | temperature | | Resistance | |
| | ratio | (° C.) | Strain | mΩ · cm² | Evaluation |
| Comparative | — | — | ◯ | 197 | X |
| example 1 | | | | | |
| Comparative | 10:0 | 350 | ◯ | 93.4 | X |
| example 2 | | | | | |
| Comparative | 10:0 | 400 | ◯ | 67.45 | X |
| example 3 | | | | | |
| Comparative | 10:0 | 500 | Δ | 43.22 | X |
| example 4 | | | | | |
| Comparative | 10:0 | 800 | X | 16.9 | X |
| example 5 | | | | | |
| Comparative | 7:3 | 250 | ◯ | 54.5 | X |
| example 6 | | | | | |
| Example 1 | 7:3 | 350 | ◯ | 14.65 | ◯ |
| Example 2 | 7:3 | 370 | ◯ | 9.87 | ◯ |
| Example 3 | 7:3 | 400 | ◯ | 5.38 | ◯ |
| Example 4 | 7:3 | 500 | Δ | 5.35 | ◯ |
| Comparative | 7:3 | 800 | X | 5.03 | X |
| example 7 | | | | | |

Comparative example 1 is an example in which the titanium separators were subjected neither to sputtering nor to plasma nitriding.

Comparative example 2 is an example in which a container was filled 100% with nitrogen gas, and the titanium separators were subjected to plasma nitriding at a treatment temperature of 350° C. The treatment time was five hours.

Comparative example 3 is an example in which the container was filled 100% with nitrogen gas, and the titanium separators were subjected to plasma nitriding at a treatment temperature of 400° C. The treatment time was five hours.

Comparative example 4 is an example in which the container was filled 100% with nitrogen gas, and the titanium separators were subjected to plasma nitriding at a treatment temperature of 500° C. The treatment time was five hours.

Comparative example 5 is an example in which the container was filled 100% with nitrogen gas, and the titanium separators were subjected to plasma nitriding at a treatment temperature of 800° C. The treatment time was five hours.

Comparative example 6 is an example in which the container was filled 70% with nitrogen gas and 30% with hydrogen gas, and the titanium separators were subjected to sputtering and plasma nitriding at a treatment temperature of 250° C. The treatment time was five hours.

Comparative example 7 is an example in which the container was filled 70% with nitrogen gas and 30% with hydrogen gas, and the titanium separators were subjected to sputtering and plasma nitriding at a treatment temperature of 800° C. The treatment time was five hours.

Example 1 is an example in which the container was filled 70% with nitrogen gas and 30% with hydrogen gas, and the titanium separators were subjected to sputtering and plasma nitriding at a treatment temperature of 350° C. The treatment time was five hours.

Example 2 is an example in which the container was filled 70% with nitrogen gas and 30% with hydrogen gas, and the titanium separators were subjected to sputtering and plasma nitriding at a treatment temperature of 370° C. The treatment time was five hours.

Example 3 is an example in which the container was filled 70% with nitrogen gas and 30% with hydrogen gas, and the titanium separators were subjected to sputtering and plasma nitriding at a treatment temperature of 400° C. The treatment time was five hours.

Example 4 is an example in which the container was filled 70% with nitrogen gas and 30% with hydrogen gas, and the titanium separators were subjected to sputtering and plasma nitriding at a treatment temperature of 500° C. The treatment time was five hours.

Both the strain and the contact resistance (mΩ·cm²) of the separators of comparative examples 1 through 7 and examples 1 through 4 were evaluated, and overall evaluations were made based on both of the evaluations.

Evaluation criteria for the strain were set in such a way that cases in which the strain was identified as beyond the allowable limits as a result of visual inspection of the strain in the titanium separators were evaluated as “×,” cases in which the strain was identified as within the allowable limits were evaluated as “Δ”, and cases in which the strain was minimal were evaluated as “◯.” The evaluations “◯” and “Δ” were “good,” and the evaluation “×” is “poor.”

Evaluation criteria for the contact resistance were set in such a way that cases in which the contact resistance of the separators exceeded 16.9 mΩ·cm² were evaluated as “poor,” and cases in which the contact resistance was 16.9 mΩ·cm² or less were evaluated as “good.”

The reasons for setting the evaluation criterion for the contact resistance at 16.9 mΩ·cm² will be described below.

Performing plasma nitriding on the surfaces of a titanium separator is believed to minimize the contact resistance of the separator.

As described in the background art, the plasma nitriding process requires a heating temperature to be approximately 700° C. for oxygen to properly diffuse in a separator surface.

Contact resistance obtained by performing the plasma nitriding process at a heating temperature of 700° C. can therefore be chosen as the criterion for the contact resistance. However, the conditions were set more rigorously in this case, and the contact resistance obtained by performing the plasma nitriding process at a heating temperature of 800° C., i.e., the contact resistance of 16.9 mΩ·cm² obtained by performing the plasma nitriding process under the conditions in comparative example 5, was chosen as the evaluation criterion.

Thus, the overall evaluations were “◯” (“good”) in cases in which the evaluation criterion for the strain was “good” and in which the evaluation criterion for the contact resistance was also “good.” The overall evaluations of all other cases were “×” (“poor”).

Conditions for measuring contact resistance are as described below.

The positive-side diffusion layer 17 and the negative-side diffusion layer 18 shown in FIG. 1 were overlaid with a piece of carbon paper (not shown) on the side that was in contact with the titanium separator 13. The separators 13, 13 were thereby brought into contact with a piece of carbon paper on the positive-side diffusion layer 17 and negative-side diffusion layer 18 when the titanium separators 13, 13 were disposed on the two sides 12a, 12b of the membrane electrode assembly 12.

One separator 13 was sandwiched between two sheets of carbon paper, and contact resistance was measured when a contact pressure of 10 kgf/cm² was applied by sandwiching the separator 13. The evaluation of good or poor was made based on the measured contact resistance.

In other words, a contact resistance of 16.9 mΩ·cm² was a value achieved when the sheets of carbon paper were brought into contact with both sides of the separator 13.

The fuel cell element 11 shown in FIG. 1 was obtained by bringing one side of each of the separators 13 into contact with the positive-side diffusion layer 17 or the negative-side diffusion layer 18. The contact resistance was thereby substantially the same as in Table 1.

The evaluation results are described below.

Comparative example 1: The strain was minimal, and the evaluation of the strain was “◯.” The contact resistance was 197 mΩ·cm², which was greater than the evaluation criterion (16.9 mΩ·cm²), and the evaluation of the contact resistance was therefore “×.” The overall evaluation was “×” (“poor”) because the evaluation of the contact resistance was “×.”

Comparative example 2: The strain was minimal, and the evaluation of the strain was therefore “◯.” The contact resistance was 93.4 mΩ·cm², which was greater than 16.9 mΩ·cm², and the evaluation of the contact resistance was therefore “×.” The overall evaluation was “×” because the evaluation of the contact resistance was “×.”

Comparative example 3: The strain was minimal, and the evaluation of the strain was therefore “◯.” The contact resistance was 67.45 mΩ·cm², which was greater than 16.9 mΩ·cm², and the evaluation of the contact resistance was therefore “×.” The total evaluation was “×” because the evaluation of the contact resistance was “×.”

Comparative example 4: The strain was within the allowable range, and the evaluation of the strain was therefore “Δ.” The contact resistance was 22 mΩ·cm², which was greater than 16.9 mΩ·cm², and the evaluation of the contact resistance was therefore “×.” The total evaluation was “×” because the evaluation of the contact resistance was “×.”

Comparative example 5: The strain exceeded the allowable range, and the evaluation of the strain was therefore “×.” The evaluation was based on contact resistance (16.9 mΩ·cm²), and the evaluation of the contact resistance was therefore “◯.” The total evaluation was “×” because the evaluation of the strain was “×.”

Comparative example 6: The strain was minimal, and the evaluation of the strain was therefore “◯.” The contact resistance was 54.5 mΩ·cm², which was greater than 16.9 mΩ·cm², and the evaluation of the contact resistance was therefore “×.” The overall evaluation was “×” because the evaluation of the contact resistance was “×.”

Comparative example 7: The strain exceeded the allowable range, and the evaluation of the strain was therefore “×.” The contact resistance was 5.03 mΩ·cm², which is less than 16.9 mΩ·cm², and the evaluation of the contact resistance was therefore “◯.” The overall evaluation was “×” because the evaluation of the strain is “×.”

Example 1: The strain was minimal, and the evaluation of the strain was therefore “◯.” The contact resistance was 14.65 mΩ·cm², which is less than 16.9 mΩ·cm², and the evaluation of the contact resistance was therefore “◯.” The overall evaluation was “◯” (“good”) because the evaluations of the strain and contact resistance were “◯.”

Example 2: The strain was minimal, and the evaluation of the strain was therefore “◯.” The contact resistance was 9.87 mΩ·cm², which is less than 16.9 mΩ·cm², and the evaluation of the contact resistance was therefore “◯.” The overall evaluation was “◯” because the evaluations of the strain and contact resistance were “◯.”

Example 3: The strain was minimal, and the evaluation of the strain was therefore “◯.” The contact resistance was 5.38 mΩ·cm², which is less than 16.9 mΩ·cm², and the evaluation of the contact resistance was therefore “◯.” The overall evaluation was “◯” because the evaluations of the strain and contact resistance were “◯.”

Example 4: The strain was within the allowable range, and the evaluation of the strain was therefore “Δ.” The contact resistance was 5.35 mΩ·cm², which is less than 16.9 mΩ·cm², and the evaluation of the contact resistance was therefore “◯.” The overall evaluation was “◯” because the evaluations of the strain and contact resistance were “Δ” and “◯.”

FIG. 8 shows a graph of the contact resistance with respect to the treatment temperatures of the separators. The vertical axis represents the contact resistance (mΩ·cm²), and the horizontal axis represents the treatment temperatures (° C.). Graph g1 represents a separator processed by plasma nitriding only, and graph g2 represents a separator processed by both sputtering and plasma nitriding.

Graph g1 represents a relationship between the contact resistance and the treatment temperatures of comparative examples 2 through 5, and graph g2 represents a relationship between the contact resistance and the treatment temperatures of comparative examples 6 and 7, and examples 1 through 4.

It follows from graphs g1 and g2 that it is in examples 1 through 4 and comparative example 7 that the contact resistance could be reduced to or below the evaluation criterion (16.9 mΩ·cm²) of comparative example 5.

In comparative example 7, the treatment temperature is high at 800° C., and the strain in the separator therefore exceeds the allowable range. As a result, it is understood that examples 1 through 4 are cases in which the contact resistance can be reduced to the evaluation criterion (16.9 mΩ·cm²) or less, and the strain in the separator can be properly minimized.

The treatment temperature of example 1 is 350° C., the treatment temperature of example 2 is 370° C., the treatment temperature of example 3 is 400° C., and the treatment temperature of example 4 is 500° C. It is thereby understood that contact resistance can be reduced to a desirable value by setting the treatment temperature of plasma nitriding to a range of 350 to 500° C.

It is also understood from Table 1 that the strain in the separator can be minimized by setting the treatment temperature of plasma nitriding to the range of 350 to 500° C.

A method for manufacturing a separator according to the second embodiment of the invention is described next based on FIGS. 3A through 4B and FIGS. 9A through 11C.

As shown in FIGS. 3A and 3B, a titanium separator blank 51 is obtained by press-forming a titanium sheet 61 with the pressing machine 62.

As shown in FIGS. 4A and 4B, the surface 21 of the separator blank 51 is oxidized and an oxide film (natural oxide film) 66 is formed on the surface 21 during transportation of the separator blank 51 or by allowing the separator blank 51 to stand in the air. The oxide film 66 stabilizes when formed to a thickness t1 of 1 to 10 nm.

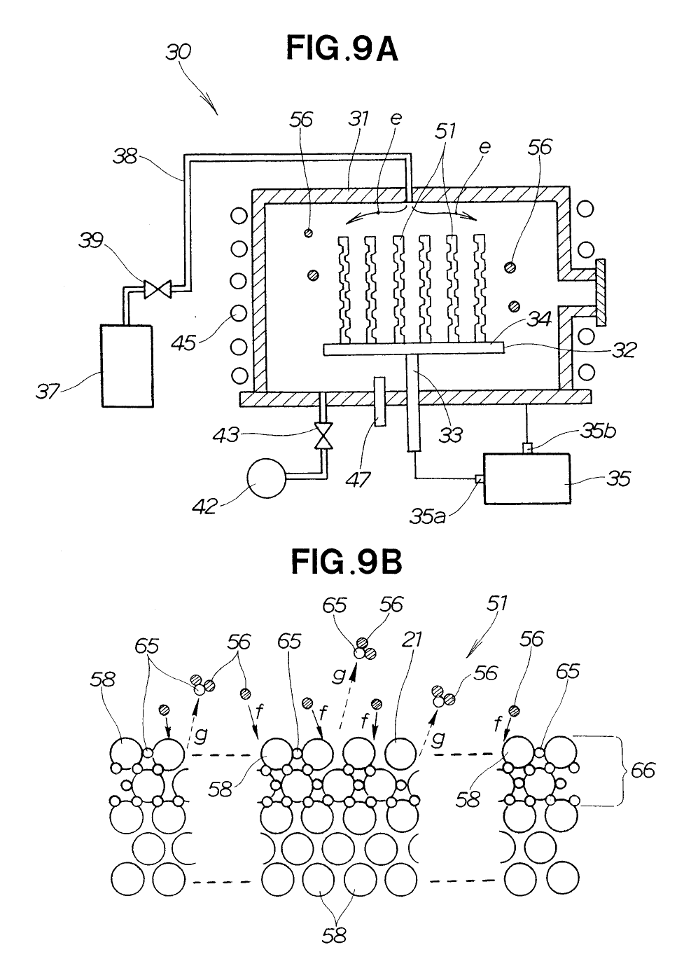

FIGS. 9A and 9B show an example in which hydrogen gas is ionized in the method for manufacturing a separator according to the second embodiment.

In FIG. 9A, a plurality of separator blanks 51 is placed vertically on the mounting plate 34 at prescribed intervals.

The second on/off valve 43 is subsequently opened and the vacuum pump 42 is actuated. The second on/off valve 43 is closed and the vacuum pump 42 is stopped, after which the second on/off valve 43 is opened and hydrogen gas 56 is supplied from the gas source 37 into the container 31 as indicated by arrows e. A reducing atmosphere is thereby created in the container 31. In this state, a prescribed voltage is applied between the container 31 and the mounting base 32 from the DC power supply 35, whereby a glow discharge is generated between the container 31 and the mounting base 32.

In FIG. 9B, a glow discharge is generated and the hydrogen gas 56 is ionized. The ionized hydrogen ions 56 are moved toward the surface 21 of each of the separator blanks 51 as indicated by arrows f. The moved hydrogen ions 56 are caused to collide with the surface 21 of the separator blank 51, and sputtering is performed.

Sputtering causes the hydrogen ions 56 to react with oxygen 65 in the surface 21 to create water vapor. The oxide film 66 is removed from the surface 21 of the separator blank 51 by removing the oxygen 65 from the surface 21 as indicated by arrows g.

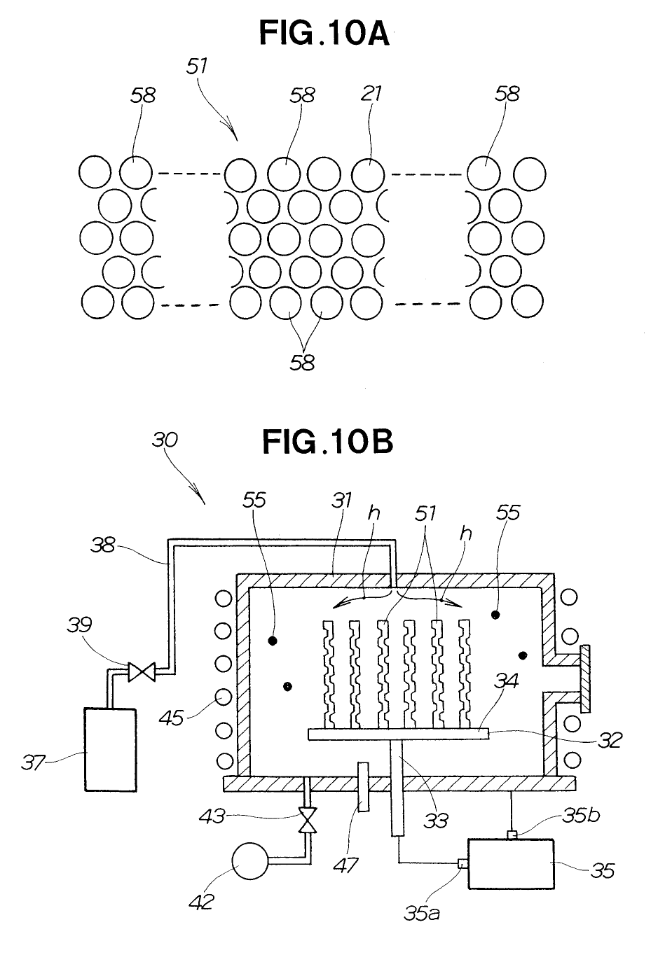

FIGS. 10A and 10B show an example in which nitrogen gas is ionized in the manufacturing method of the second embodiment.

FIG. 10A shows a state in which the oxide film 66 (see FIG. 9B) is removed from the surface 21 of the separator blank 51.

In FIG. 10B, the second on/off valve 43 is opened, the vacuum pump 42 is driven, and the hydrogen gas is discharged from the container 31.

The second on/off valve 43 is closed and the vacuum pump 42 is stopped, after which the second on/off valve 43 is opened and the nitrogen gas 55 is supplied from the gas source 37 into the container 31 as indicated by the arrows h. A nitriding atmosphere is thereby created in the container 31.

The pressure inside the container 31 is detected by the gas pressure sensor 47 and confirmed to be, for example, 67 to 1333 Pa (0.5 to 10 Torr). The second on/off valve 43 is closed.

The container is heated by the heater 45 so that the treatment temperature reaches 350 to 500° C. The separator blank 51 is heated to a range of 350 to 500° C.

In this state, a prescribed voltage is applied between the container 31 and the mounting base 32 from the DC power supply 35, whereby a glow discharge is generated between the container 31 and the mounting base 32.

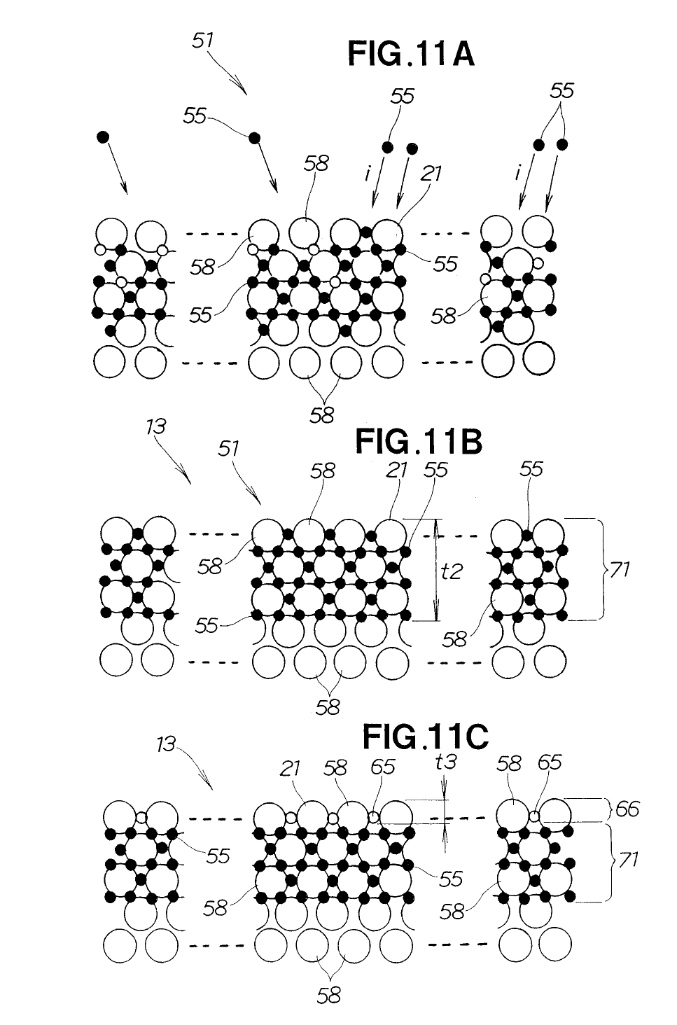

FIGS. 11A through 11C show an example in which nitrogen is diffused on a separator surface in the manufacturing method according to the second embodiment.

In FIG. 11A, a glow discharge is generated and a nitrogen gas 55 is ionized. The ionized nitrogen ions 55 migrate toward the surface 21 of a separator blank 51 as indicated by the arrows i. The nitrogen ions 55 that have migrated are caused to collide with the surface 21 of the separator blank 51, and plasma nitriding is performed.

At this point, an oxide film 66 is removed from the surface 21 of the separator blank 51 by sputtering as described with reference to FIG. 9B. The nitrogen 55 is thereby diffused more readily on the surface 21 of the separator blank 51 when the nitrogen ions 55 are caused to collide with the surface 21 of the separator blank 51 due to plasma nitriding.

In FIG. 11B, the nitrogen 55 is diffused more readily on the surface 21 of the separator blank 51, making it possible to reduce the temperature of the plasma nitriding process to a range of 350 to 500° C. In other words, the nitrogen 55 can be adequately diffused on the surface 21 of the separator blank 51 merely by heating the separator blank 51 to a temperature of 350 to 500° C.

The separator 13 is obtained by completing the plasma nitriding treatment. The separator 13 is provided with a titanium nitride film 71 obtained by adequately diffusing the nitrogen 55 in the surface 21. The surface 21 of the separator 13 will be less likely to oxidize as a result.

The titanium nitride film 71 preferably has a thickness t2 of 0.1 to 3.0 μm, in a manner similar to that of the first embodiment.

If the film thickness t2 is less than 0.1 μm, the titanium nitride film 71 will be too thin to minimize the oxide film (natural oxide film) 66. The film thickness t2 is set to 0.1 μm or greater to minimize the oxide film (natural oxide film) 66.

On the other hand, if the film thickness t2 exceeds 3.0 μm, the titanium nitride film 71 will be too thick to ensure the toughness required of the separator. In addition, too much time is required to perform plasma nitriding, and complications are encountered in achieving increased productivity. The film thickness t2 is therefore set to 3.0 μm or less, to ensure the toughness for the separator and productivity.

In FIG. 11C, when the separator 13 is being transported, or as a result of the separator 13 being placed in atmospheric air, the titanium nitride film 71 formed on the surface 21 of the separator 13 will oxidize, and the oxide film (natural oxide film) 66 will be formed on the surface 21.

The titanium nitride film 71 will be formed on the surface 21 of the separator 13; therefore, oxidation on the surface 21 of the separator 13 will tend not to occur, and it will be possible to prevent the oxide film 66 (natural oxide film) from forming. Accordingly, the oxide film 66 will be stably held at a very small thickness t3 of 0 to 1 nm.

According to the method for manufacturing a fuel cell separator of the second embodiment, the step of manufacturing the separator 13 can be simplified by performing plasma nitriding at the same time that sputtering is performed. The manufacturing time of the separator 13 can thereby be reduced and productivity can be increased.

According to the method for manufacturing a separator of the second embodiment, it is possible to minimize the treatment temperature, i.e., the heating temperature relating to the separator blank 51 (see FIG. 6B), to 350 to 500° C. during the plasma nitriding treatment. The separator 13 that has undergone the plasma nitriding treatment can thereby be prevented from developing strain.

In the first and the second embodiments, a description was provided with reference to a case wherein hydrogen gas was used as a reducing gas during sputtering, the hydrogen gas was ionized and caused to collide with the oxide film 66, and the hydrogen was reacted with oxygen so that the oxide film was chemically removed. However, the reducing gas is not limited thereto. A halogen gas (HCI, CI₂, HF, or the like), ammonia (NH₃) gas, argon (Ar) gas, or the like can be used instead of hydrogen gas.

If argon (Ar) gas is used, the argon gas is ionized and caused to collide with the oxide film 66 during sputtering, as a result of which the oxide film will be physically removed. The same effect as the one obtained in the foregoing examples can thereby be exhibited.

The reducing gas can be selected from among hydrogen gas, halide gases, ammonia gas, and a variety of other gases, allowing for increased design flexibility.

In the foregoing examples, a description was provided with reference to a case wherein nitrogen gas was used as a nitriding gas, and the nitrogen gas was ionized and caused to collide with the surface 21 of the separator 13 during plasma nitriding, so that the titanium nitriding film 71 was formed on the surface 21. However, the nitriding gas is not limited thereto. Ammonia (NH₃) gas can be used, for example, instead of nitrogen gas. The nitriding gas can be selected from among nitrogen gas, ammonia gas, and the like, allowing for increased design flexibility.

Additionally, if ammonia gas is used as a nitriding gas, the ammonia gas can be also used as a reducing gas, allowing the equipment to be simplified.

In the foregoing examples, furthermore, a description was provided with reference to a case wherein the proportion of nitrogen gas 55 to hydrogen gas 56 in the container 31 was set to be in a nitrogen gas/hydrogen gas ratio of 7:3. However, the ratio of the nitrogen gas and the hydrogen gas is not limited thereto, and any desired ratio can be selected.

In the foregoing examples, a description was also provided for examples wherein the treatment time was set at five hours. However, the treatment time is not limited thereto; any desired treatment time can be selected.

In the second embodiment, a description was also provided for an example wherein a single apparatus 30 for manufacturing a fuel cell separator was used for the sputtering and plasma nitriding treatments. However, the method is not limited thereto; an apparatus for sputtering and an apparatus for plasma nitriding can each be used separately.

### INDUSTRIAL APPLICABILITY

The method for manufacturing a fuel cell separator according to the present invention is particularly useful for the manufacture of a titanium separator.

1. A method for manufacturing a titanium separator for use in a fuel cell, said method comprising the steps of:
press-forming a titanium sheet into a separator blank with grooves formed for conducting gas or water;
sputtering, after the separator blank is placed in a reducing atmosphere containing a reducing gas, ions produced by ionizing the reducing gas onto a surface of the separator blank to thereby remove an oxide film generated on the separator blank surface; and
plasma-nitriding the separator blank surface by, after the oxide-film-removed separator blank is placed in a nitriding atmosphere containing a nitriding gas, heating the separator blank to a temperature of 350 to 500° C. and then causing ions produced by plasma-nitriding the nitriding gas to collide with the separator blank surface to thereby form a nitrogen diffused layer on the surface.

2. The method of claim 1, wherein the reducing gas includes at least one gas selected from the group containing hydrogen gas, halide gas, and ammonia gas.

3. The method of claim 1, wherein the nitriding gas includes at least one gas selected from the group containing nitrogen gas and ammonia gas.

4. The method of claim 1, wherein the sputtering and plasma-nitriding steps are performed simultaneously.
